(19) United States
(12) Patent Application Publication
(10) Pub. No.: US 2026/0068755 A1
(43) Pub. Date: Mar. 5, 2026

(54) MEMORY DEVICE

(71) Applicant: SK hynix Inc., Gyeonggi-do (KR)

(72) Inventor: Heon Yong CHANG, Gyeonggi-do (KR)

(21) Appl. No.: 19/012,899

(22) Filed: Jan. 8, 2025

(30) Foreign Application Priority Data
Sep. 3, 2024 (KR) 10-2024-0118978

(51) Int. Cl. H01L 25/07; H10B 80/00

(52) U.S. Cl. CPC H01L 25/074; H10B 80/00

(57) ABSTRACT

According to an embodiment of the present disclosure, a memory device may include a first semiconductor chip including a first bonding insulating layer, a second semiconductor chip bonded to the first semiconductor chip, and including a second bonding insulating layer, and a through contact extending from an interior of the first semiconductor chip to an interior of the second semiconductor chip and penetrating at least one opening region of the first bonding insulating layer and the second bonding insulating layer. A width of the opening region may be greater than a width of the through contact.

### CROSS-REFERENCE TO RELATED APPLICATION

The present application claims priority under 35 U.S.C. 119 (a) to Korean patent application number 10-2024-0118978 filed on Sep. 3, 2024, which is incorporated herein by reference in its entirety.

### TECHNICAL FIELD

The embodiments of the present disclosure relate generally to semiconductor technology and, more particularly, to a memory device.

### BACKGROUND

A memory device is an important component in the electronics industry owing to its characteristics such as miniaturization, multi-functionality, and/or low manufacturing cost. As the electronics industry develops, memory devices are gradually becoming more highly integrated. High integration of the memory device requires reducing the line width of wiring included in the memory device which increases the process difficulty of making the memory device.

One method for achieving high integration is currently under development which includes making separately two wafers, one with memory cells and another with peripheral circuits and bonding the two wafers together. However, the process of bonding the wafers still requires improvement to ensure the two wafers are evenly attached without lifting or gaps between them.

### SUMMARY

Embodiments of the present disclosure may provide an elegant solution that improves bonding between different wafers. The embodiments provide a memory device employing such an inventive method to ensure that process defects are prevented because of poor bonding between different wafers. The embodiments provide a memory device which exhibits improved performance and is capable of preventing deterioration of device characteristics due to process defects.

Embodiments of the present disclosure may provide a memory device including a first semiconductor chip including a first bonding insulating layer, a second semiconductor chip bonded to the first semiconductor chip, and including a second bonding insulating layer, and a through contact extending from an interior of the first semiconductor chip to an interior of the second semiconductor chip and penetrating at least one opening region of the first bonding insulating layer and the second bonding insulating layer, wherein a width of the opening region is greater than a width of the through contact.

Embodiments of the present disclosure may provide a memory device including a bonding insulating layer including a first bonding insulating layer, and a second bonding insulating layer disposed on the first bonding insulating layer and bonded to the first bonding insulating layer, a buffer layer disposed within the bonding insulating layer, and disposed in the same layer as at least one of the first bonding insulating layer and the second bonding insulating layer, and a through contact penetrating the buffer layer in a vertical direction.

Embodiments of the present disclosure may provide a memory device including a bonding insulating layer including a first bonding insulating layer, and a second bonding insulating layer disposed on the first bonding insulating layer and bonded to the first bonding insulating layer, at least one of the first bonding insulating layer and the second bonding insulating layer including an opening region, a buffer layer disposed within the opening region, and a through contact penetrating the buffer layer in a vertical direction.

According to an embodiment of the present disclosure, it is possible to prevent the deterioration of device characteristics of a memory device due to process defects.

These and other features and advantages of the present invention will become better understood by those with ordinary skill in the art from the following detailed description in conjunction with the following drawings.

### BRIEF DESCRIPTION OF THE DRAWINGS

FIG. 1 illustrates a cross-sectional structure of a memory device according to an embodiment of the present disclosure.

FIGS. 2 to 4 illustrate other cross-sectional structures of a memory device according to an embodiment of the present disclosure.

FIGS. 5 to 16 illustrate methods for forming a memory device according to embodiments of the present disclosure.

FIGS. 17 to 25 illustrate other methods for forming a memory device according to embodiments of the present disclosure.

### DETAILED DESCRIPTION

Hereinafter, various embodiments of the present disclosure will be described in detail with reference to accompanying drawings.

In the attached drawings, two directions parallel to an upper surface of a substrate are defined as a first direction FD and a second direction SD, respectively, and a direction protruding vertically from the upper surface of the substrate is defined as a third direction VD. The first direction FD and the second direction SD may be substantially perpendicular to each other. The third direction VD may be a direction perpendicular to the first direction FD and the second direction SD. In the following specification, ‘vertical’ or ‘vertical direction’ will be used to have substantially the same meaning as the third direction VD. The direction indicated by an arrow in the drawings and its opposite direction may indicate the same direction.

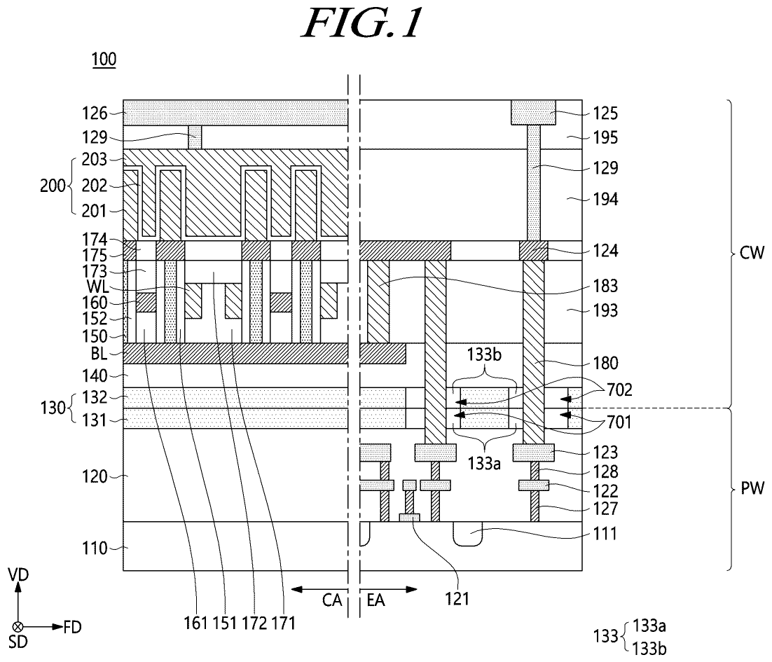

FIG. 1 illustrates a cross-sectional structure of a memory device according to an embodiment of the present disclosure.

Referring to FIG. 1, a memory device 100 according to an embodiment of the present disclosure may include a cell area CA and an extension area EA. The cell area CA may include memory cells. The extension area EA may be disposed adjacent to the cell area CA in the first direction FD. The extension area EA may be located at an outer periphery of the cell area CA. In an embodiment, the extension area EA may be located at an outer periphery of the cell area CA in a first direction FD. The extension area EA includes a plurality of contacts for connecting memory cells with a peripheral circuit. For example, there may be disposed a contact for connecting a bit line BL to a peripheral circuit in the extension area EA located outside the cell area CA in the first direction FD.

The memory device 100 according to an embodiment of the present disclosure may include a substrate 110, a device isolation layer 111, a first insulating layer 120, a plurality of wirings 121, 122, 123, 124, 125 and 126, a plurality of contacts 127, 128 and 129, a bonding insulating layer 130, a buffer layer 133, a second insulating layer 140, a bit line BL, an active layer 150, a first gate insulating layer 151, a second gate insulating layer 152, a back gate electrode 160, a gate capping layer 161, a first insulating pattern 171, a second insulating pattern 172, a third insulating pattern 173, a fourth insulating pattern 174, a word line WL, a contact plug 175, a through contact 180, a third insulating layer 193, a fourth insulating layer 194, a fifth insulating layer 195, and a capacitor 200. The bonding insulating layer 130 may include a first bonding insulating layer 131 and a second bonding insulating layer 132. The buffer layer 133 may include a first buffer layer 133a and a second buffer layer 133b. The capacitor 200 may include a lower electrode 201, a dielectric layer 202, and an upper electrode 203.

The substrate 110 may include a semiconductor substrate such as a silicon wafer or a silicon-on-insulator (SOI) wafer. The substrate 110 may include an III-V group semiconductor substrate, for example, a compound semiconductor substrate such as GaAs. The substrate 110 may include single crystal silicon, polysilicon, amorphous silicon, single crystal silicon germanium, polycrystalline silicon germanium, carbon-doped silicon, or a combination thereof.

In the extension area EA, at least one device isolation layer 111 may be disposed within the substrate 110. The device isolation layer 111 may be formed using a trench device isolation technology such as shallow trench isolation (STI). The device isolation layer 111 may include silicon oxide, silicon nitride, silicon oxynitride, low-K dielectrics, high-K dielectrics, or a combination thereof.

A first wiring 121, a first contact 127, a second wiring 122, a second contact 128, and a third wiring 123 may be sequentially disposed on the substrate 110. The first insulating layer 120 may be disposed to cover the first wiring 121, the first contact 127, the second wiring 122, the second contact 128, and the third wiring 123. The first wiring 121, the second wiring 122, and the first contact 127 may form one transistor included in a peripheral circuit. In an embodiment, a voltage for operating a bit line BL may be transmitted through the first contact 127 and the second wiring 122.

The first insulating layer 120 may be made of any suitable material including silicon oxide, silicon nitride, silicon oxynitride, a high-k dielectric, or a combination thereof. The first wiring 121, the first contact 127, the second wiring 122, the second contact 128, and the third wiring 123 may include a conductive material such as a metal, a metal oxide, a metal nitride, a metal silicide, polysilicon, conductive carbon, or a combination thereof.

The first bonding insulating layer 131 may be disposed on the first insulating layer 120. The second bonding insulating layer 132 may be disposed on the upper surface of the first bonding insulating layer 131. The lower surface of the second bonding insulating layer 132 may directly contact the upper surface of the first bonding insulating layer 131. The lower surface of the second bonding insulating layer 132 may be bonded to the upper surface of the first bonding insulating layer 131. In an embodiment, the memory device 100 may include a structure in which a first semiconductor chip PW including a first bonding insulating layer 131 and a second semiconductor chip CW including a second bonding insulating layer 132 are bonded together at the interface of the first and second bonding insulating layers 131 and 132. The first semiconductor chip PW may be referred to as a peri-wafer, and the second semiconductor chip CW may be referred to as a cell wafer.

The bonding insulating layer 130 may include silicon oxide, silicon nitride, silicon oxynitride, silicon carbonitride, a high-k dielectric, or a combination thereof. In an embodiment, the first bonding insulating layer 131 and the second bonding insulating layer 132 may include silicon carbonitride.

The first bonding insulating layer 131 and the second bonding insulating layer 132 may include at least one opening region 701 or 702. In an embodiment, the opening regions 701 and 702 may extend in the second direction SD. Alternatively, in an embodiment, the opening regions 701 and 702 may have a shape surrounding the through contact 180 around the through contact 180. The opening region 701 of the first bonding insulating layer 131 and the opening region 702 of the second bonding insulating layer 132 may overlap with each other in the vertical direction.

The first buffer layer 133a may be disposed within the opening region 701 of the first bonding insulating layer 131. The first buffer layer 133a may fill the inside of the opening region 701 of the first bonding insulating layer 131. The second buffer layer 133b may be disposed within the opening region 702 of the second bonding insulating layer 132. The second buffer layer 133b may fill the inside of the opening region 702 of the second bonding insulating layer 132. The first buffer layer 133a and the second buffer layer 133b may overlap in the vertical direction. The upper surface of the first buffer layer 133a may directly contact the lower surface of the second buffer layer 133b. The upper surface of the first buffer layer 133a may be bonded to the lower surface of the second buffer layer 133b within the opening regions 701 and 702 of the bonding insulating layer 130.

The buffer layer 133 may be disposed on the side surface of the through contact 180. In an embodiment, the buffer layer 133 may surround at least a portion of the side surface of the through contact 180. The buffer layer 133 may be positioned between the through contact 180 and the bonding insulating layer 130. Since the buffer layer 133 is located between the through contact 180 and the bonding insulating layer 130, the through contact 180 may not contact the bonding insulating layer 130.

An interface between the first buffer layer 133a and the second buffer layer 133b may be coplanar or substantially coplanar with an interface between the first bonding insulating layer 131 and the second bonding insulating layer 132. The lower surface of the first buffer layer 133a may be coplanar or substantially coplanar with the lower surface of the first bonding insulating layer 131. The upper surface of the second buffer layer 133b may be coplanar or substantially coplanar with the upper surface of the second bonding insulating layer 132.

The buffer layer 133 may include silicon oxide, silicon nitride, silicon oxynitride, silicon carbonitride, a high-k dielectric, or a combination thereof. In an embodiment, the buffer layer 133 may include a material different from the material forming the bonding insulating layer 130. In an embodiment, the first buffer layer 133a and the second buffer layer 133b may include oxide. Alternatively, in an embodiment, the first buffer layer 133a and the second buffer layer 133b may include polysilicon.

The second insulating layer 140 may be disposed on the second bonding insulating layer 132. The bit line BL may be disposed on the second insulating layer 140. The bit line BL may extend along the first direction FD. The bit line BL may extend from the cell area CA to the extension area EA along the first direction FD. The second insulating layer 140 may include silicon oxide, silicon nitride, silicon oxynitride, silicon carbonitride, a high-k dielectric material, or a combination thereof. The bit line BL may include a conductive material, such as a metal, a metal nitride, a metal silicide, polysilicon, conductive carbon, or a combination thereof.

A memory cell may be disposed on a bit line BL in the cell area CA. In an embodiment, the memory cell may include one transistor and one capacitor. Hereinafter, it will be described that the memory cell includes one transistor and one capacitor.

The active layer 150 may contact the bit line BL, and may extend in a vertical direction. The active layer 150 may include a channel region formed in an area overlapping with the word line WL or the back gate electrode 160 in a first direction FD. The active layer 150 may include a source or drain region formed around the channel region. The active layer 150 may include polysilicon or single crystal silicon.

The first gate insulating layer 151 and the second gate insulating layer 152 may be disposed on a side surface of the active layer 150. The first gate insulating layer 151 may be disposed between the active layer 150 and the word line WL in the first direction FD. The first gate insulating layer 151 may extend in the vertical direction. The second gate insulating layer 152 may be disposed between the active layer 150 and the back gate electrode 160 in the first direction FD. The second gate insulating layer 152 may extend in the vertical direction. The first and second gate insulating layers 151 and 152 may include silicon oxide, silicon nitride, silicon oxynitride, silicon carbonitride, a high-k dielectric, or a combination thereof.

The word line WL, the first insulating pattern 171, and the second insulating pattern 172 may be disposed between the opposing first gate insulating layers 151. The vertical length of the word line WL may be less than the vertical length of the active layer 150. The first insulating pattern 171 may be located between the opposing word lines WL. The first insulating pattern 171 may cover one side and the lower surface of the word line WL. The second insulating pattern 172 may cover the upper surfaces of the first insulating pattern 171 and of the word line WL.

The back gate electrode 160, the gate capping layer 161, and the third insulating pattern 173 may be located between the opposing second gate insulating layers 152. The vertical length of the back gate electrode 160 may be less than the vertical length of the active layer 150. The gate capping layer 161 may be positioned between the back gate electrode 160 and the bit line BL. The third insulating pattern 173 may be positioned on the back gate electrode 160. The gate capping layer 161, the back gate electrode 160, and the third insulating pattern 173 may overlap with each other in the vertical direction.

The word line WL and the back gate electrode 160 may include a conductive material such as a metal, a metal nitride, a metal silicide, polysilicon, a conductive carbon, or a combination thereof. The first insulating pattern 171, the second insulating pattern 172, the third insulating pattern 173, the fourth insulating pattern 174, and the gate capping layer 161 may include silicon oxide, silicon nitride, silicon oxynitride, silicon carbon nitride, a high-k dielectric, or a combination thereof.

The fourth insulating pattern 174 and the contact plug 175 may be disposed on the active layer 150, the first and second gate insulating layers 151 and 152, the second insulating pattern 172, and the third insulating pattern 173. Each contact plug 175 may correspond to one active layer 150. Each contact plug 175 may directly contact the upper surface of the corresponding active layer 150. The fourth insulating pattern 174 may be disposed between each pair of adjacent contact plugs 175. Each contact plug 175 may include a conductive material such as a metal, a metal nitride, a metal silicide, polysilicon, a conductive carbon, or a combination thereof. The fourth insulating pattern 174 may include silicon oxide, silicon nitride, silicon oxynitride, silicon carbon nitride, a high-k dielectric, or a combination thereof.

A bit line connection contact 183 may be disposed on the bit line BL in the extension area EA. A fourth wiring 124 and a fourth insulating pattern 174 may be disposed on the bit line connection contact 183.

The through contact 180 may be disposed on a third wiring 123. The through contact 180 may extend in a vertical direction. The through contact 180 may extend into the first insulating layer 120 by penetrating the third insulating layer 193, the second insulating layer 140, the second buffer layer 133b, and the first buffer layer 133a in the vertical direction. The lower surface of the through contact 180 may directly contact the third wiring 123 which is disposed inside the first insulating layer 120. The upper surface of the through contact 180 may directly contact the fourth wiring 124. The bit line BL may be electrically connected to the third wiring 123 through the bit line connection contact 183, the fourth wiring 124, and the through contact 180. The through contact 180 may be disposed on the periphery of the area where the bit line BL is disposed in the first direction FD.

The bit line connection contact 183, the fourth wiring 124, and the through contact 180 may include a conductive material such as a metal, a metal oxide, a metal nitride, a metal silicide, polysilicon, conductive carbon, or a combination thereof.

The capacitor 200 may be disposed on the fourth insulating pattern 174 and the contact plug 175 in the cell area CA. The lower electrode 201 of each capacitor 200 may correspond to one contact plug 175 and may directly contact the upper surface of the contact plug 175. The dielectric layer 202 may be disposed to cover the side surface and the upper surface of the lower electrode 201 and the upper surface of the fourth insulating pattern 174. The dielectric layer 202 may conformally cover the side surface and the upper surface of the lower electrode 201. The upper electrode 203 may be disposed on the dielectric layer 202. The lower electrode 201 and the upper electrode 203 may include a conductive material such as a metal, a metal oxide, a metal nitride, a metal silicide, polysilicon, a conductive carbon, or a combination thereof. The dielectric layer 202 may include a high-k material, silicon oxide, silicon nitride, or a combination thereof.

The third contact 129 and the fifth insulating layer 195 may be disposed on the upper electrode 203. A sixth wiring 126 may be disposed on a third contact 129.

The fourth insulating layer 194 and the third contact 129 may be disposed on the fourth wiring 124 and the fourth insulating pattern 174 in the extension area EA. The third contact 129 may penetrate the fourth insulating layer 194 and contact an upper surface of at least one fourth wiring 124. The fifth insulating layer 195 may be disposed on the fourth insulating layer 194. A fifth wiring 125 may be disposed within the fifth insulating layer 195.

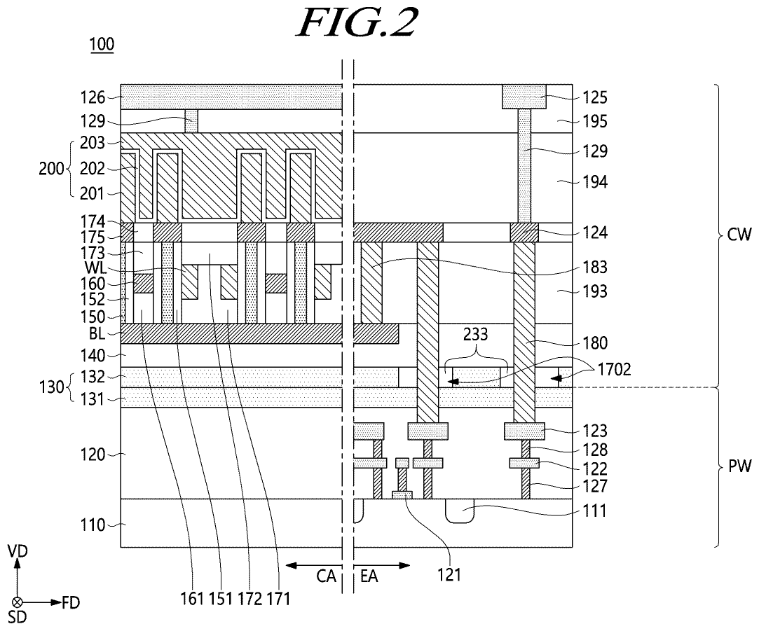

FIGS. 2 to 4 illustrate other cross-sectional structures of memory devices according to an embodiment of the present disclosure.

Hereinafter, the description of configurations which are substantially the same as those of the previous embodiments will be omitted.

Referring to FIG. 2, the memory device 100 may include a bonding insulating layer 130, a buffer layer 233, and a through contact 180.

A second bonding insulating layer 132 may include at least one opening region 1702 in which the buffer layer 233 is disposed to fill the inside of the opening region 1702. The upper surface of the first bonding insulating layer 131 may directly contact the lower surface of the buffer layer 233. The lower surface of the buffer layer 233 within the opening region 1702 of the second bonding insulating layer 132 may be bonded to the upper surface of the first bonding insulating layer 131.

The buffer layer 233 may be disposed on the side surface of the through contact 180. In an embodiment, the buffer layer 233 may surround at least a portion of a side surface of the through contact 180. The buffer layer 233 may be positioned between the through contact 180 and the second bonding insulating layer 132. The through contact 180 may not contact the second bonding insulating layer 132. The through contact 180 may penetrate the buffer layer 233 and the first bonding insulating layer 131 in a vertical direction.

An interface between the buffer layer 233 and the first bonding insulating layer 131 may be substantially coplanar with an interface between the first bonding insulating layer 131 and the second bonding insulating layer 132. The lower surface of the buffer layer 233 may be substantially coplanar with the lower surface of the second bonding insulating layer 132.

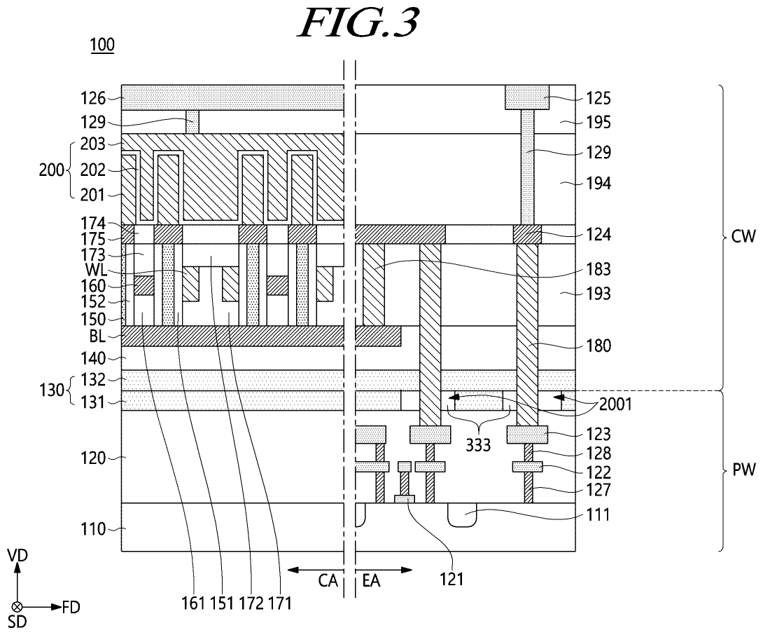

Referring to FIG. 3, the memory device 100 may include the bonding insulating layer 130, a buffer layer 333, and the through contact 180.

A first bonding insulating layer 131 may include at least one opening region 2001. The buffer layer 333 may be disposed within the opening region 2001 of the first bonding insulating layer 131. The buffer layer 333 may fill the inside of the opening region 2001 of the first bonding insulating layer 131. The lower surface of a second bonding insulating layer 132 may directly contact the upper surface of the buffer layer 333. The upper surface of the buffer layer 333 within the opening region 2001 of the first bonding insulating layer 131 may be bonded to the lower surface of the second bonding insulating layer 132.

The buffer layer 333 may be disposed on the side surface of the through contact 180. In an embodiment, the buffer layer 333 may surround at least a portion of the side surface of the through contact 180. The buffer layer 333 may be located between the through contact 180 and the first bonding insulating layer 131. The through contact 180 may not contact the first bonding insulating layer 131. The through contact 180 may penetrate the buffer layer 333 and the second bonding insulating layer 132 in the vertical direction.

An interface between the buffer layer 333 and the second bonding insulating layer 132 may be coplanar or substantially coplanar with an interface between the first bonding insulating layer 131 and the second bonding insulating layer 132. The upper surface of the buffer layer 333 may be coplanar or substantially coplanar with the upper surface of the first bonding insulating layer 131.

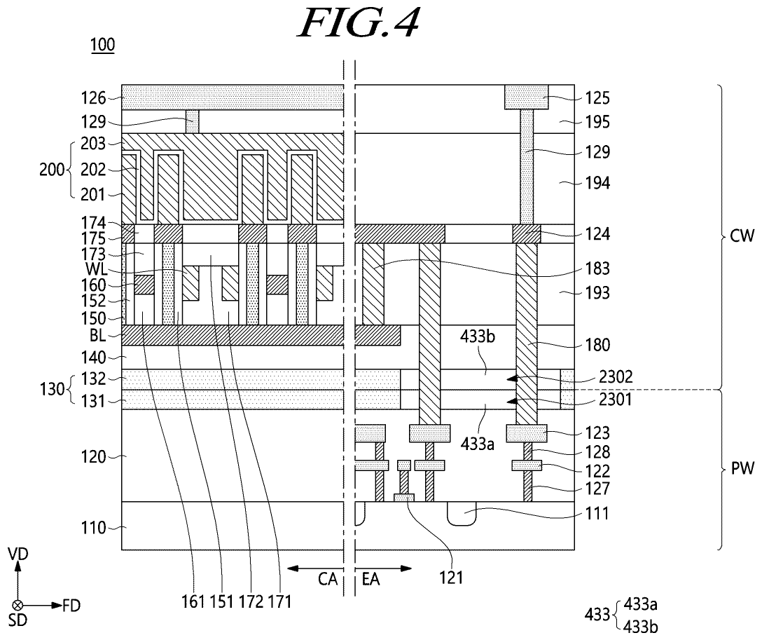

Referring to FIG. 4, the memory device 100 may include the bonding insulating layer 130, a buffer layer 433, and the through contact 180.

A first bonding insulating layer 131 and a second bonding insulating layer 132 may include at least one opening region 2301 or 2302. The opening regions 2301 and 2302 may extend in the first direction FD. In an embodiment, the opening regions 2301 and 2302 may overlap with two adjacent through contacts 180 in the vertical direction. That is, the bonding insulating layer 130 may not be disposed between adjacent through contacts 180. The opening region 2301 of the first bonding insulating layer 131 and the opening region 2302 of the second bonding insulating layer 132 overlap with each other in the vertical direction.

A first buffer layer 433a may be disposed within the opening region 2301 of the first bonding insulating layer 131. The first buffer layer 433a may fill the inside of the opening region 2301 of the first bonding insulating layer 131. A second buffer layer 433b may be disposed within the opening region 2302 of the second bonding insulating layer 132. The second buffer layer 433b may fill the inside of the opening region 2302 of the second bonding insulating layer 132. The first buffer layer 433a and the second buffer layer 433b may overlap with each other in the vertical direction. The upper surface of the first buffer layer 433a may directly contact the lower surface of the second buffer layer 433b. The upper surface of the first buffer layer 433a may be bonded to the lower surface of the second buffer layer 433b within the opening regions 2301 and 2302 of the bonding insulating layer 130.

The buffer layer 433 may be disposed on the side surface of the through contact 180. In an embodiment, the buffer layer 433 may surround at least a portion of the side surface of the through contact 180. At least a portion of the buffer layer 433 may be positioned between the through contact 180 and the bonding insulating layer 130. Since at least a portion of the buffer layer 433 is positioned between the through contact 180 and the bonding insulating layer 130, the through contact 180 may not contact the bonding insulating layer 130.

An interface between the first buffer layer 433a and the second buffer layer 433b may be coplanar or substantially coplanar with an interface between the first bonding insulating layer 131 and the second bonding insulating layer 132. The lower surface of the first buffer layer 433a may be coplanar or substantially coplanar with the lower surface of the first bonding insulating layer 131. The upper surface of the second buffer layer 433b may be coplanar or substantially coplanar with the upper surface of the second bonding insulating layer 132.

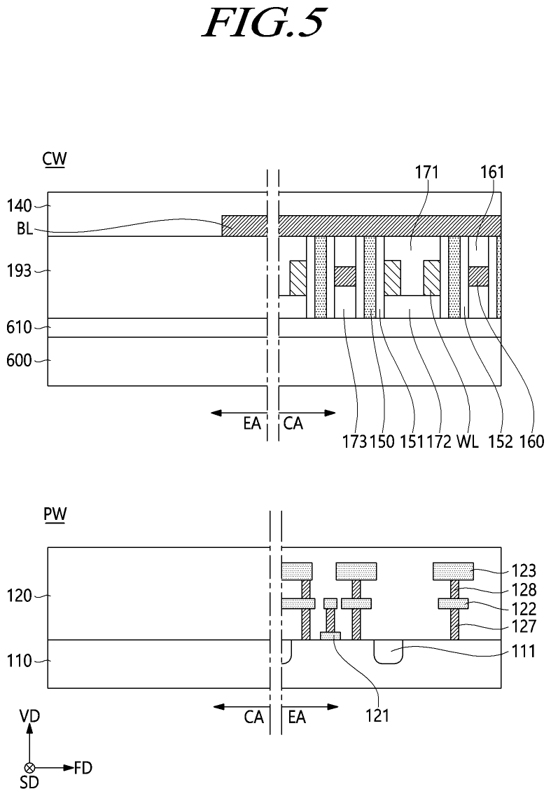

FIGS. 5 to 16 illustrate methods for forming a memory device according to embodiments of the present disclosure.

Referring to FIG. 5, a second semiconductor chip CW and a first semiconductor chip PW may be prepared. The second semiconductor chip CW may include a first substrate 600, a sixth insulating layer 610 formed on the first substrate 600, a third insulating layer 193 formed on the sixth insulating layer 610, an active layer 150, a first gate insulating layer 151, a second gate insulating layer 152, a word line WL, a back gate electrode 160, a gate capping layer 161, a first insulating pattern 171, a second insulating pattern 172, and a third insulating pattern 173, and a bit line BL and a second insulating layer 140 formed on the third insulating layer 193.

The first semiconductor chip PW may include a substrate 110, a device isolation layer 111 formed within the substrate 110, a first wiring 121 formed on the substrate 110, a first contact 127, a second wiring 122, a second contact 128, a third wiring 123, and a first insulating layer 120.

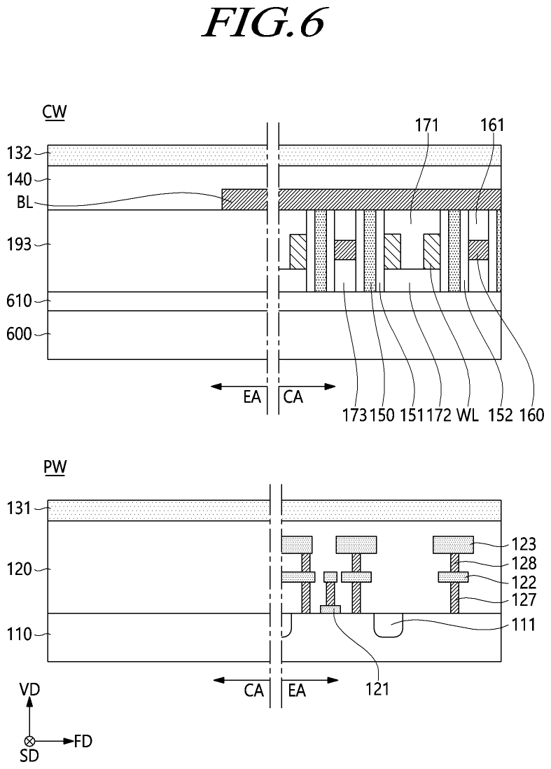

Referring to FIG. 6, a second bonding insulating layer 132 may be formed on the second insulating layer 140 of the second semiconductor chip CW. A first bonding insulating layer 131 may be formed on the first insulating layer 120 of the first semiconductor chip PW. The first bonding insulating layer 131 may include the same material as the material forming the second bonding insulating layer 132. In an embodiment, the first bonding insulating layer 131 and the second bonding insulating layer 132 may include silicon carbon nitride.

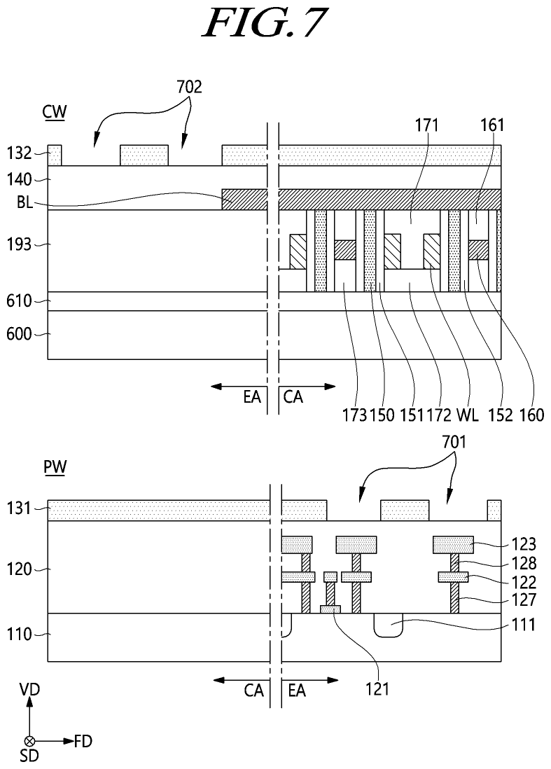

Referring to FIG. 7, at least one opening region 702 may be formed in the second bonding insulating layer 132 of the second semiconductor chip CW. The opening region 702 may be formed in the extension area EA. In an embodiment, the first bonding insulating layer 131 may be positioned between two adjacent opening regions 701. The opening region 702 may expose an upper surface of the second insulating layer 140. At least one opening region 701 may be formed in the first bonding insulating layer 131 of the first semiconductor chip PW. The opening region 701 may be formed in the extension area EA. In an embodiment, the second bonding insulating layer 132 may be positioned between two adjacent opening regions 702. The opening region 701 may expose the upper surface of the first insulating layer 120. The process of forming the opening regions 701 and 702 within the first bonding insulating layer 131 and the second bonding insulating layer 132 may include an etching process.

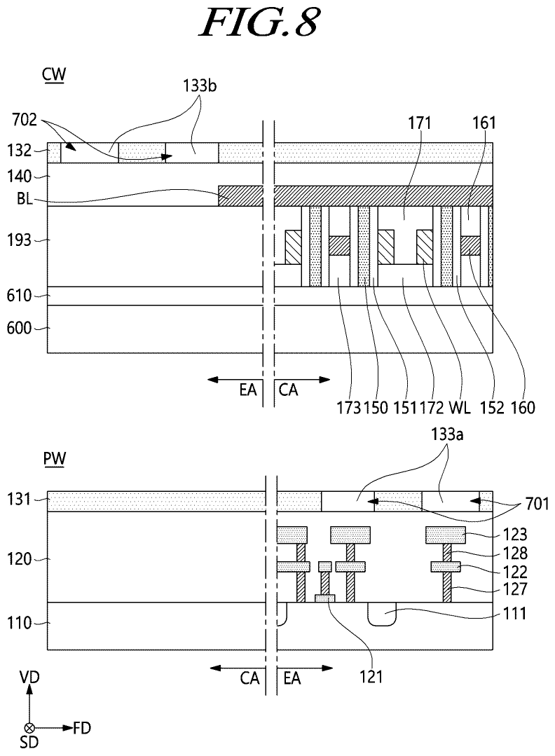

Referring to FIG. 8, a first buffer layer 133a may be formed within the opening region 701 of the first bonding insulating layer 131. A second buffer layer 133b may be formed within the opening region 702 of the second bonding insulating layer 132. The upper surface of the first buffer layer 133a may be coplanar or substantially coplanar with the upper surface of the first bonding insulating layer 131. One side (e.g., the upper side) of the second buffer layer 133b may be coplanar or substantially coplanar with one side (e.g., the upper side) of the second bonding insulating layer 132.

The first buffer layer 133a and the second buffer layer 133b may include a material different from the material forming the first bonding insulating layer 131 and the second bonding insulating layer 132. The first buffer layer 133a may include the same material as the material forming the second buffer layer 133b. In an embodiment, the first buffer layer 133a and the second buffer layer 133b may include an oxide. Alternatively, the first buffer layer 133a and the second buffer layer 133b may include polysilicon.

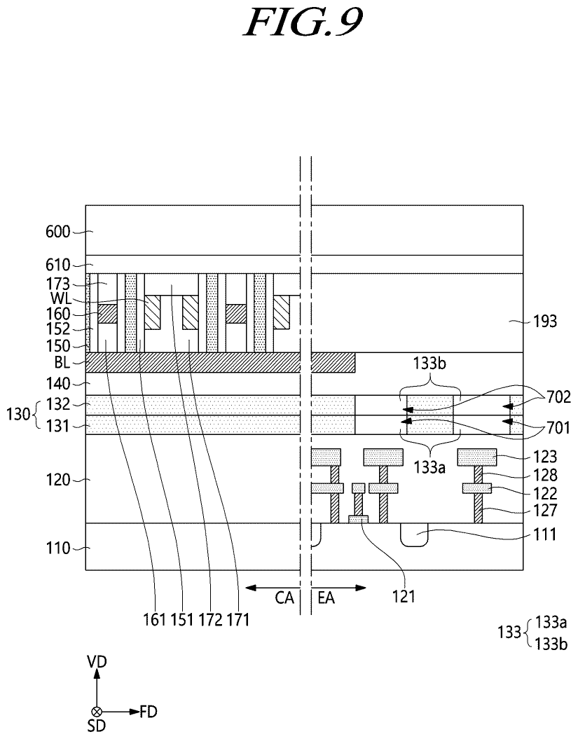

Referring to FIG. 9, the second semiconductor chip CW may be bonded on the first semiconductor chip PW. The lower surface of the second bonding insulating layer 132 of the second semiconductor chip CW may be bonded to the upper surface of the first bonding insulating layer 131 of the first semiconductor chip PW.

In the extension area EA, the first buffer layer 133a and the second buffer layer 133b may overlap with each other in the vertical direction. The upper surface of the first buffer layer 133a may directly contact the lower surface of the second buffer layer 133b. An interface between the first buffer layer 133a and the second buffer layer 133b may be in the same plane with an interface between the first bonding insulating layer 131 and the second bonding insulating layer 132.

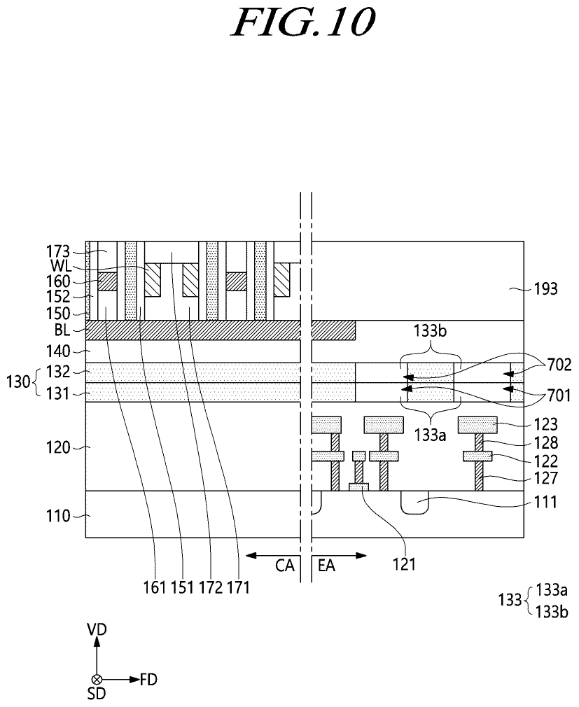

Referring to FIG. 10, the first substrate 600 and the sixth insulating layer 610 may be removed. In an embodiment, the first substrate 600 may be removed through a grinding process or a chemical mechanical polishing (CMP) process. In an embodiment, the sixth insulating layer 610 may be removed through a wet-etching process.

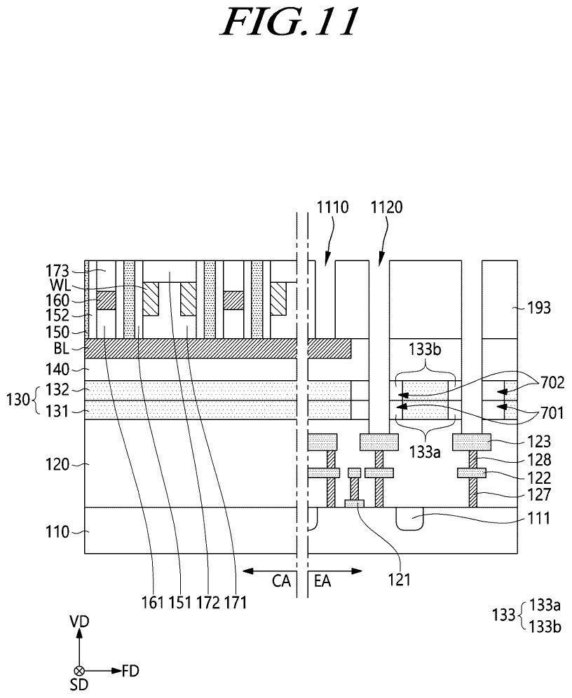

Referring to FIG. 11, a first through hole 1110 and a second through hole 1120 may be formed in the extension area EA. The first through hole 1110 may penetrate the third insulating layer 193 in a vertical direction to expose an upper surface of the bit line BL. The second through hole 1120 may penetrate the third insulating layer 193, the second insulating layer 140, the second buffer layer 133b, the first buffer layer 133a, and the first insulating layer 120 in the vertical direction to expose the upper surface of a third wiring 123.

The first and second buffer layers 133a and 133b may include the same material as the material forming the first and second insulating layers 120 and 140. In an embodiment, the first insulating layer 120, the second insulating layer 140, the first buffer layer 133a, and the second buffer layer 133b may include an oxide.

The process of forming the first and second through holes 1110 and 1120 may include an anisotropic etching process. The process of forming the second through hole 1120 may include a process of sequentially etching the second insulating layer 140, the second buffer layer 133b, the first buffer layer 133a, and the first insulating layer 120. In an embodiment, the process of etching the first buffer layer 133a and the second buffer layer 133b may be performed under substantially the same conditions as the process of etching the first insulating layer 120 or the second insulating layer 140.

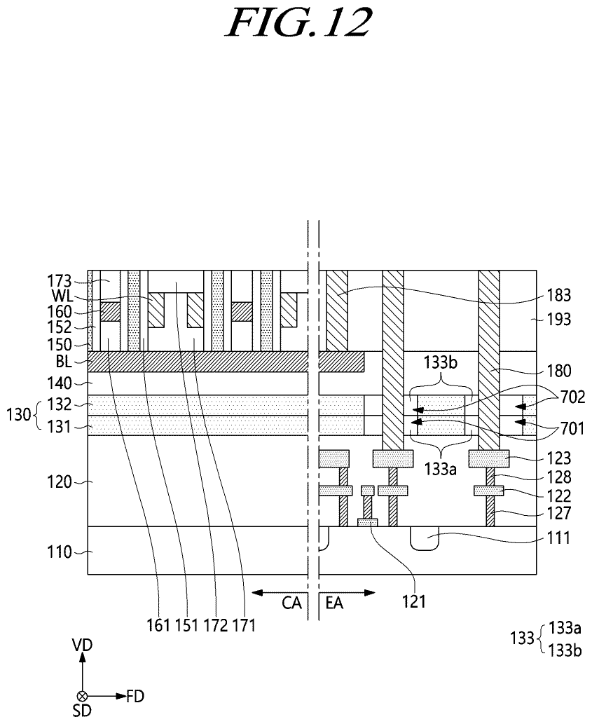

Referring to FIGS. 11 and 12, a bit line connection contact 183 may be formed in the first through hole 1110. The lower surface of the bit line connection contact 183 may directly contact the bit line BL. The through contact 180 may be formed in the second through hole 1120. The lower surface of the through contact 180 may directly contact the third wiring 123. At least a portion of the side surface of the through contact 180 may directly contact the first buffer layer 133a and the second buffer layer 133b. The bit line connection contact 183 may include the same material as the material forming the through contact 180.

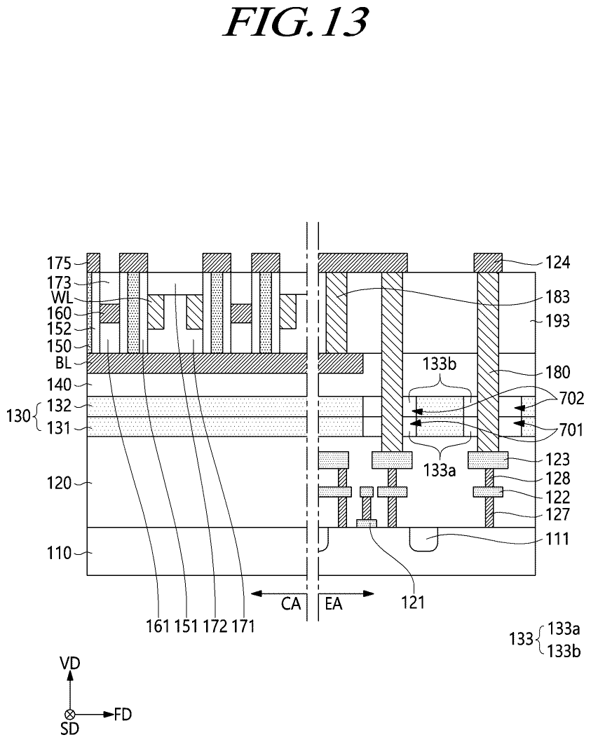

Referring to FIG. 13, in the cell area CA, the contact plug 175 may be formed on the corresponding active layer 150. The lower surface of the contact plug 175 may directly contact the upper surface of the corresponding active layer 150. In the extension area EA, the fourth wiring 124 may be formed on the bit line connection contact 183 and on the through contact 180. At least one fourth wiring 124 may electrically connect the bit line connection contact 183 and the through contact 180. The bit line BL may be electrically connected to the third wiring 123 through the bit line connection contact 183, the at least one fourth wiring 124 connected to the bit line connection contact 183, and the through contact 180 connected to the at least one fourth wiring 124.

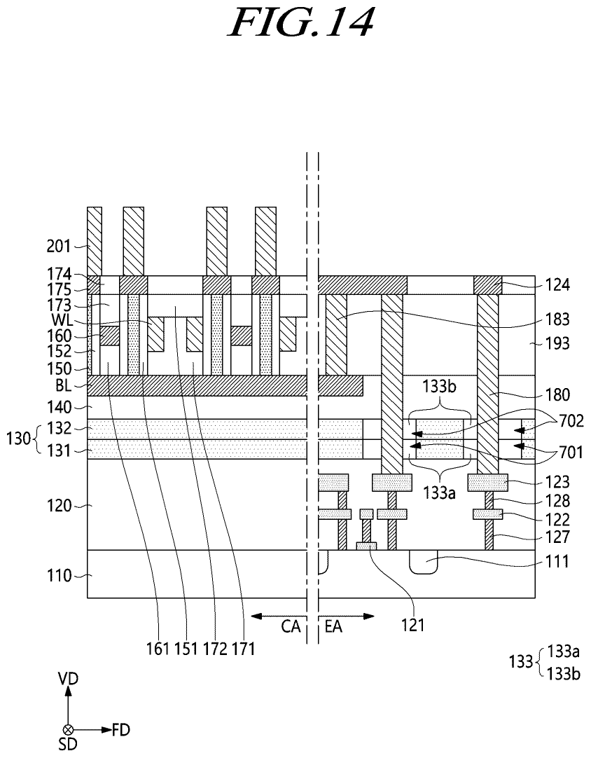

Referring to FIG. 14, there may be formed a fourth insulating pattern 174 covering the contact plug 175 and the fourth wiring 124. The fourth insulating pattern 174 may fill the spaces between the contact plugs 175. The fourth insulating pattern 174 may also fill the spaces between the fourth wirings 124.

After the fourth insulating pattern 174 is formed, a lower electrode 201 may be formed on the contact plug 175 in the cell area CA. The lower electrode 201 may be formed on the upper surface of a corresponding contact plug 175. The lower surface of the lower electrode 201 may directly contact the upper surface of the contact plug 175.

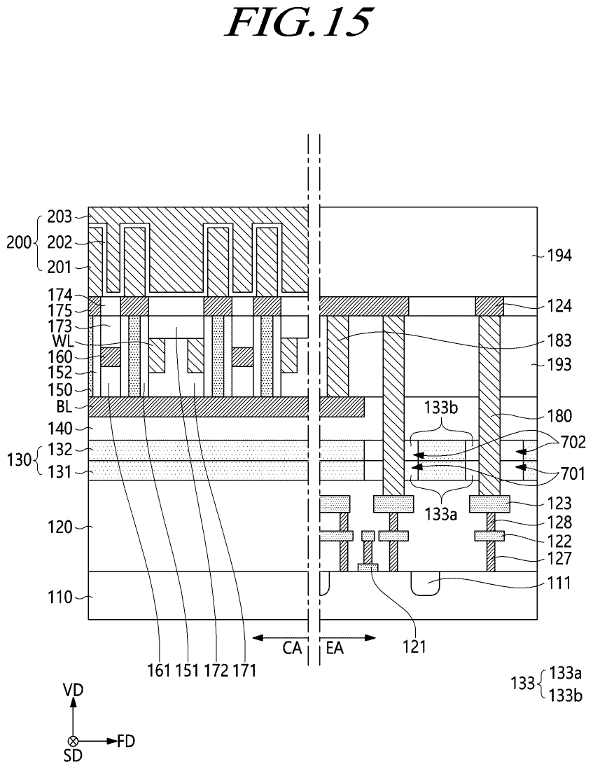

Referring to FIG. 15, a dielectric layer 202 may be formed on the lower electrode 201 and the fourth insulating pattern 174 in the cell area CA. In an embodiment, the dielectric layer 202 may be conformally formed on the side and upper surfaces of the lower electrode 201. The dielectric layer 202 may cover the side and upper surfaces of the lower electrode 201 and the upper surface of the fourth insulating pattern 174. An upper electrode 203 may be formed on the dielectric layer 202. The dielectric layer 202 and the upper electrode 203 may not be disposed in the extension area EA. The fourth insulating layer 194 may be formed in the extension area EA.

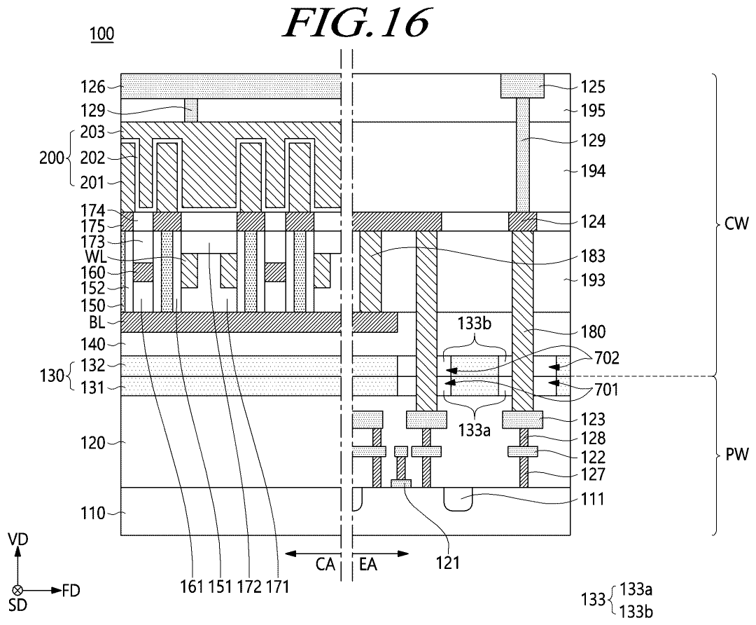

Referring to FIG. 16, a fifth insulating layer 195 may be formed on the upper electrode 203 and the fourth insulating layer 194. After the fifth insulating layer 195 is formed, a third contact 129 penetrating the fifth insulating layer 195 may be formed in both the extension area EA and in the cell area CA. In the cell area CA, the third contact 129 may directly contact the upper surface of the upper electrode 203. In the extension area EA, the third contact 129 may directly contact the upper surface of the fourth wiring 124.

A sixth wiring 126 may be formed on the third contact 129 in the cell area CA. A fifth wiring 125 may be formed on the third contact 129 in the extension area EA. The fifth and sixth wirings 125 and 126 may each be formed within the fifth insulating layer 195.

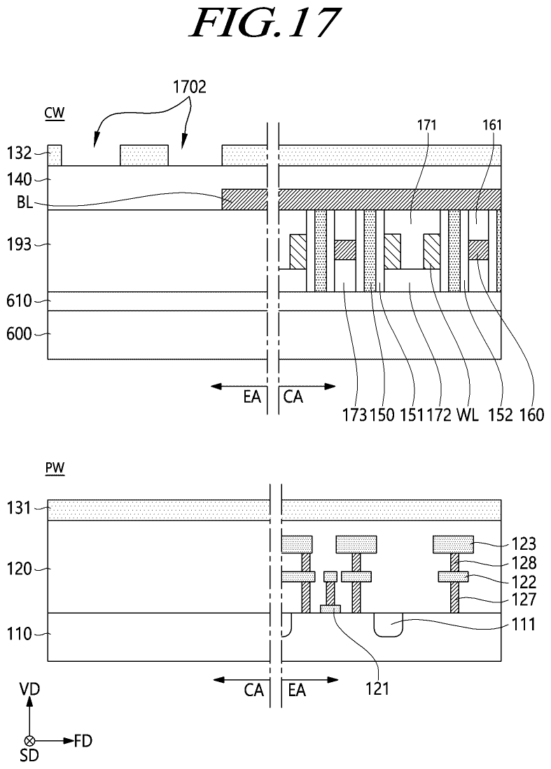

FIGS. 17 to 25 illustrate other methods for forming a memory device according to embodiments of the present disclosure.

The memory device illustrated in FIG. 17 may be formed by the same method as the method described with reference to FIGS. 5 and 6.

Referring to FIG. 17, at least one opening region 1702 may be formed within the second bonding insulating layer 132 of the second semiconductor chip CW. The opening region 1702 may be formed within the extension area EA. The opening region 1702 may expose the upper surface of the second insulating layer 140. The process of forming the opening region 1702 within the second bonding insulating layer 132 may include an etching process. The opening region 1702 may not be formed within the first bonding insulating layer 131 of the first semiconductor chip PW.

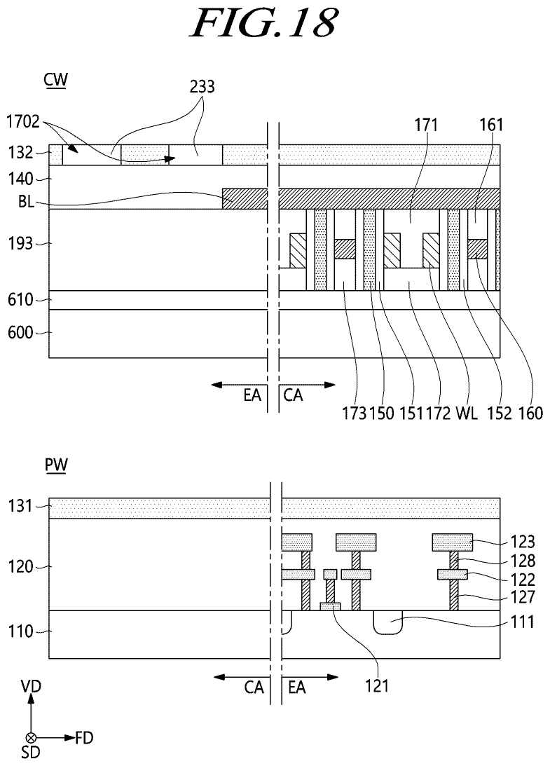

Referring to FIG. 18, a buffer layer 233 may be formed within the opening region 1702 of the second bonding insulating layer 132. One side (e.g., the upper side) of the buffer layer 233 may be coplanar or substantially coplanar with one side (e.g., the upper side) of the second bonding insulating layer 132. In an embodiment, the buffer layer 233 may include an oxide.

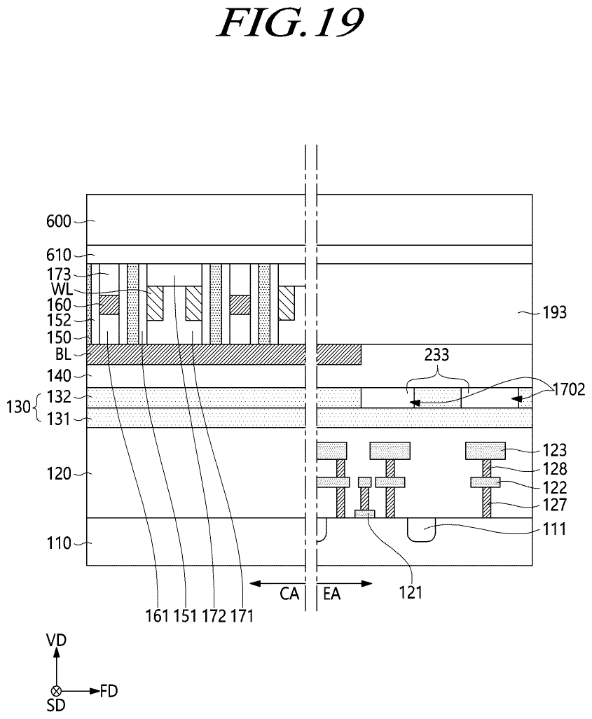

Referring to FIG. 2 and FIG. 19, the second semiconductor chip CW may be bonded on the first semiconductor chip PW. The lower side of the second bonding insulating layer 132 may be bonded to the upper side of the first bonding insulating layer 131. The lower side of the buffer layer 233 may directly contact the upper side of the first bonding insulating layer 131. An interface between the buffer layer 233 and the first bonding insulating layer 131 may be coplanar or substantially coplanar with an interface between the first and second bonding insulating layers 131 and 132.

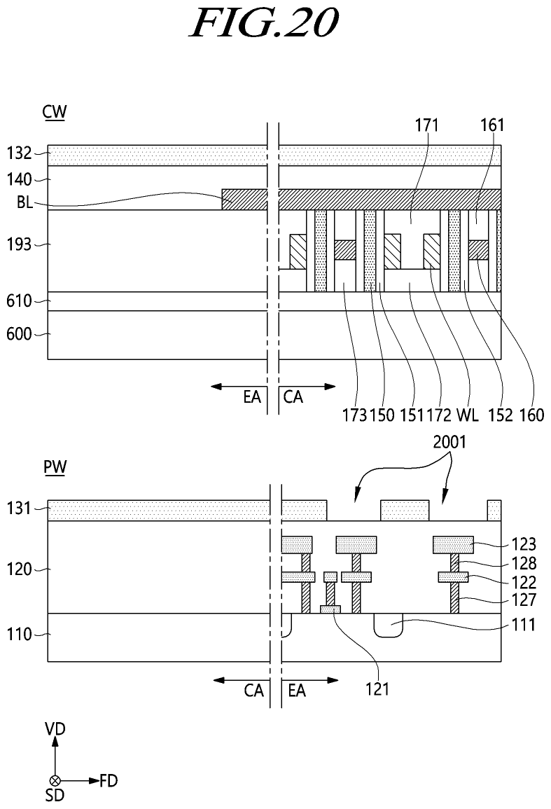

The memory device illustrated in FIG. 20 may be formed by the same method as the method described with reference to FIGS. 5 and 6.

Referring to FIG. 20, at least one opening region 2001 may be formed in the first bonding insulating layer 131 of the first semiconductor chip PW. The opening region 2001 may be formed in the extension area EA. The opening region 2001 may expose the upper surface of the first insulating layer 120. The process of forming the opening region 2001 in the first bonding insulating layer 131 may include an etching process. The opening region 2001 may not be formed in the second bonding insulating layer 132 of the second semiconductor chip CW.

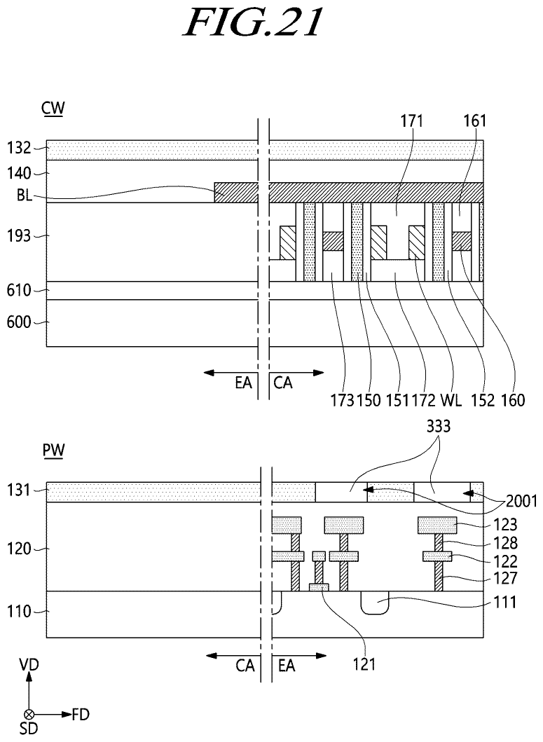

Referring to FIG. 21, a buffer layer 333 may be formed within the opening region 2001 of the first bonding insulating layer 131. The upper surface of the buffer layer 333 may be coplanar or substantially coplanar with the upper surface of the first bonding insulating layer 131. In an embodiment, the buffer layer 333 may include an oxide.

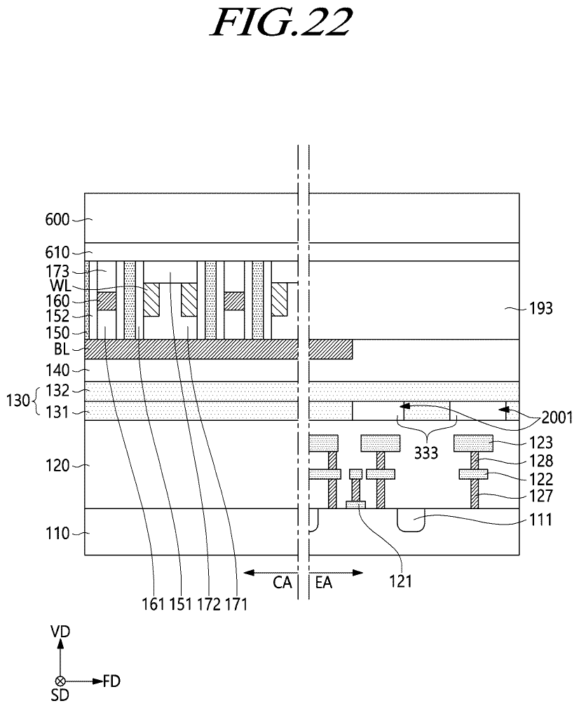

Referring to FIG. 3 and FIG. 22, the second semiconductor chip CW may be bonded on the first semiconductor chip PW. The lower surface of the second bonding insulating layer 132 may be bonded to the upper surface of the first bonding insulating layer 131. The upper surface of the buffer layer 333 may directly contact the lower surface of the second bonding insulating layer 132. An interface between the buffer layer 333 and the second bonding insulating layer 132 may be coplanar or substantially coplanar with an interface between the first bonding insulating layer 131 and the second bonding insulating layer 132.

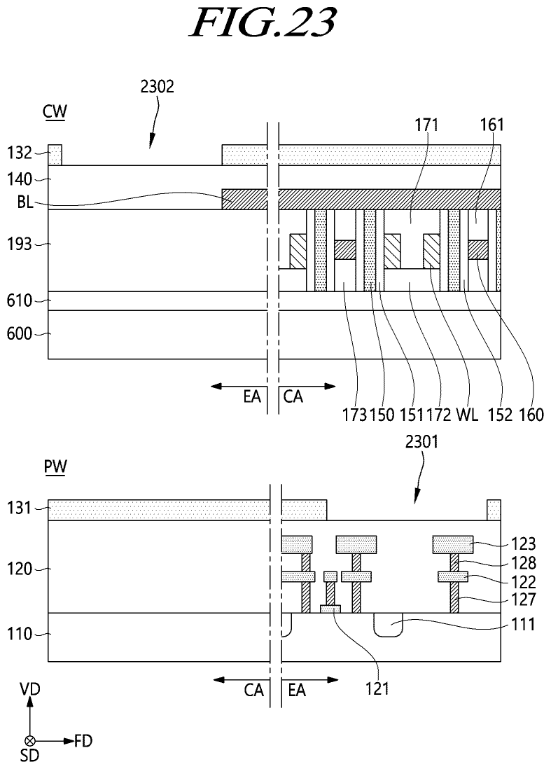

The memory device illustrated in FIG. 23 may be formed by the same method described with reference to FIGS. 5 and 6.

Referring to FIG. 23, at least one opening region 2302 may be formed in the second bonding insulating layer 132 of the second semiconductor chip CW. At least one opening region 2301 may be formed in the first bonding insulating layer 131 of the first semiconductor chip PW. The opening region 2301 may be formed in the extension area EA. The opening region 2301 in the first bonding insulating layer 131 may expose the upper surface of the first insulating layer 120. The opening region 2302 in the second bonding insulating layer 132 may expose the upper surface of the second insulating layer 140. The process of forming the opening regions 2302, 2301 in the first and second bonding insulating layers 131 and may include an etching process.

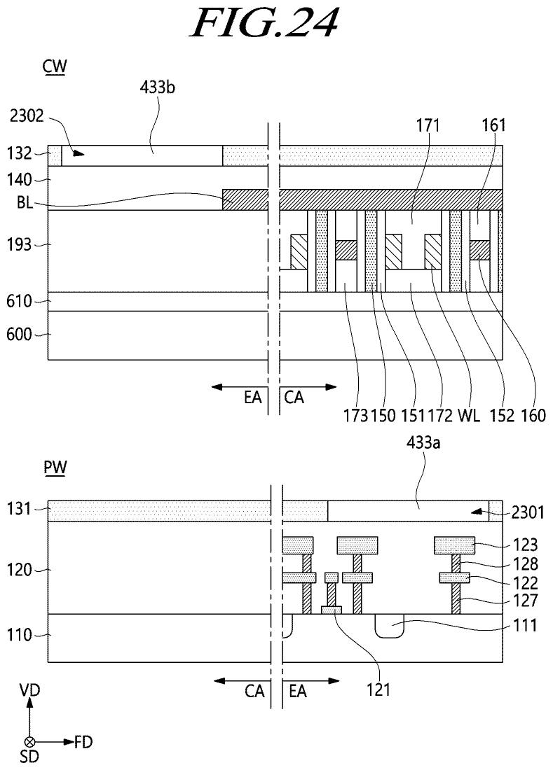

Referring to FIG. 24, a first buffer layer 433a may be formed in the opening region 2301 of the first bonding insulating layer 131. A second buffer layer 433b may be formed in the opening region 2302 of the second bonding insulating layer 132. The upper surface of the first buffer layer 433a may be coplanar or substantially coplanar with the upper surface of the first bonding insulating layer 131. One surface (e.g., the upper surface) of the second buffer layer 433b may be substantially coplanar with one surface (e.g., the upper surface) of the second bonding insulating layer 132. In an embodiment, the first buffer layer 433a and the second buffer layer 433b may include oxide.

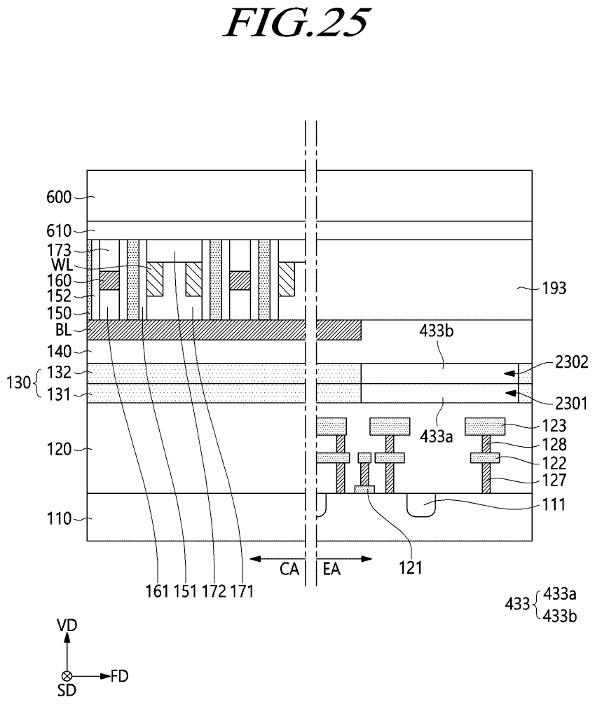

Referring to FIG. 4 and FIG. 25, the second semiconductor chip CW may be bonded on the first semiconductor chip PW. The lower surface of the second bonding insulating layer 132 may be bonded to the upper surface of the first bonding insulating layer 131. The upper surface of the first buffer layer 433a may directly contact the lower surface of the second buffer layer 433b. The interface between the first buffer layer 433a and the second buffer layer 433b may be coplanar or substantially coplanar with the interface between the first bonding insulating layer 131 and the second bonding insulating layer 132.

Referring again to FIG. 1 to FIG. 4, the memory device 100 according to the embodiments of the present disclosure may include the first bonding insulating layer 131 and the second bonding insulating layer 132 bonded to the upper surface of the first bonding insulating layer. An opening region 701, 702, 1702, 2001, 2301 or 2302 may be disposed in at least one of the first bonding insulating layer 131 and the second bonding insulating layer 132. The buffer layer 133, 233, 333 or 433 may be disposed within the opening region 701, 702, 1702, 2001, 2301 or 2302. A through contact 180 may vertically penetrate the buffer layer 133, 233, 333 or 433.

According to an embodiment of the present disclosure, since the buffer layer 133 is disposed within at least one of the first bonding insulating layer 131 and the second bonding insulating layer 132, the delamination of a bonding interface located between adjacent through contacts 180 may be prevented. Specifically, stress may accumulate at the bonding interface during the process of bonding the second semiconductor chip CW and the first semiconductor chip PW. In particular, the degree of stress accumulation at the bonding interface between adjacent through contacts 180 may be greater than that at other locations. If the accumulated stress between the bonding interfaces becomes greater than the bonding strength of the bonded wafers, a delamination phenomenon in which the bonding interfaces are separated may occur. However, according to the embodiments of the present disclosure, the buffer layer 133 may be disposed on the side of the through contact 180, and may absorb the stress occurring at the bonding interface, thereby suppressing the delamination or the lifting of the bonding interface. Therefore, the memory device according to the embodiments of the present disclosure may prevent deterioration of device characteristics due to process defects.

The above description and the accompanying drawings provide embodiments of the technical idea of the present disclosure for illustrative purposes only. Various modifications, additions and substitutions to the described embodiments will be readily apparent to those skilled in the art without departing from the spirit and scope of the present disclosure. In addition, since the embodiments disclosed in this disclosure are not intended to limit the technical idea of this disclosure but to describe the technical idea of this disclosure, the scope of the technical idea of this disclosure is not limited by these embodiments. The protection scope of this disclosure should be interpreted by the claims below, and all technical ideas within the equivalent scope should be interpreted as being included in the scope of the rights of this disclosure. Furthermore, the embodiments may be combined to form additional embodiments.

What is claimed is:

1. A memory device comprising:
a first semiconductor chip including a first bonding insulating layer;
a second semiconductor chip bonded to the first semiconductor chip, and including a second bonding insulating layer; and
a through contact extending from an interior of the first semiconductor chip to an interior of the second semiconductor chip and penetrating at least one opening region of the first bonding insulating layer or the second bonding insulating layer,
wherein a width of the opening region is greater than a width of the through contact.

2. The memory device of claim 1, wherein at least one of the first semiconductor chip and the second semiconductor chip further includes a buffer layer filling the opening region.

3. The memory device of claim 2, wherein the buffer layer is positioned between the through contact and at least one of the first bonding insulating layer and the second bonding insulating layer.

4. The memory device of claim 2, wherein each of the first bonding insulating layer and the second bonding insulating layer includes an opening region,
wherein the buffer layer includes a first buffer layer disposed within the opening region of the first bonding insulating layer and a second buffer layer disposed within the opening region of the second bonding insulating layer,
wherein an upper surface of the first buffer layer is bonded to a lower surface of the second buffer layer.

5. The memory device of claim 4, wherein the opening region of the first bonding insulating layer overlaps with the opening region of the second bonding insulating layer.

6. The memory device of claim 4, wherein the through contact penetrates the first buffer layer and the second buffer layer.

7. The memory device of claim 2, wherein the second bonding insulating layer includes an opening region, and a lower surface of the buffer layer is bonded to an upper surface of the first bonding insulating layer.

8. The memory device of claim 7, wherein the opening region of the second bonding insulating layer overlaps with the first bonding insulating layer.

9. The memory device of claim 7, wherein the through contact penetrates the buffer layer and the first bonding insulating layer.

10. The memory device of claim 2, wherein the first bonding insulating layer includes an opening region, and an upper surface of the buffer layer is bonded to a lower surface of the second bonding insulating layer.

11. The memory device of claim 10, wherein the opening region of the first bonding insulating layer overlaps the second bonding insulating layer.

12. The memory device of claim 10, wherein the through contact penetrates the buffer layer and the second bonding insulating layer.

13. The memory device of claim 2, wherein the bonding insulating layer includes a material different from a material forming the buffer layer.

14. A memory device comprising:
a bonding insulating layer including a first bonding insulating layer, and a second bonding insulating layer disposed on the first bonding insulating layer and bonded to the first bonding insulating layer;
a buffer layer disposed within the bonding insulating layer, and disposed in the same layer as at least one of the first bonding insulating layer and the second bonding insulating layer; and
a through contact penetrating the buffer layer in a vertical direction.

15. The memory device of claim 14, wherein the buffer layer includes a first buffer layer disposed in the same layer as the first bonding insulating layer, and a second buffer layer disposed in the same layer as the second bonding insulating layer.

16. The memory device of claim 15, wherein the first buffer layer overlaps with the second buffer layer.

17. The memory device of claim 14, wherein the buffer layer is disposed on the same layer as the second bonding insulating layer, and
wherein a lower surface of the buffer layer is bonded to an upper surface of the first bonding insulating layer.

18. The memory device of claim 14, wherein the buffer layer is disposed on the same layer as the first bonding insulating layer, and
wherein an upper surface of the buffer layer is bonded to a lower surface of the second bonding insulating layer.

19. A memory device comprising:
first and second semiconductor chips coupled together via first and second bonding insulating layers; and
a through contact extending from the first semiconductor chip to the second semiconductor chip via at least one opening region of the first bonding insulating layer or the second bonding insulating layer,
wherein at least one of the first and second semiconductor chips further includes a buffer layer filling the at least one opening region.

20. The memory device of claim 19, wherein the buffer layer is positioned between the through contact and at least one of the first bonding insulating layer or the second bonding insulating layer.
